(19) United States
(12) Patent Application Publication
(10) Pub. No.: US 2023/0231011 A1
(43) Pub. Date: Jul. 20, 2023

(54) SEMICONDUCTOR DEVICE INCLUDING VERTICAL MOSFET AND METHOD OF MANUFACTURING THE SAME

(71) Applicant: RENESAS ELECTRONICS CORPORATION, Tokyo (JP)

(72) Inventor: Satoru Tokuda, Tokyo (JP)

(21) Appl. No.: 18/189,463

(22) Filed: Mar. 24, 2023

Related U.S. Application Data
(63) Continuation of application No. 16/782,802, filed on Feb. 5, 2020.

(30) Foreign Application Priority Data
Feb. 7, 2019 (JP) 2019-020340

(51) Int. Cl. H01L 29/06; H01L 29/66; H01L 29/423

(52) U.S. Cl. CPC H01L 29/0634; H01L 29/66734; H01L 29/4238; H01L 29/4236

(57) ABSTRACT

A semiconductor device that achieves both miniaturization and high breakdown voltage is disclosed. The semiconductor device has a gate electrode G1 formed in a trench TR extending in Y direction and a plurality of column regions PC including column regions PC1 to PC3 formed in a drift region ND. The column regions PC1, PC2 and PC3 are provided in a staggered manner to sandwich the trench TR. An angle θ1 formed by a line connecting the centers of the column regions PC1 and PC2 and a line connecting the centers of the column regions PC1 and PC3 is 60 degrees or more and 90 degrees or less.

### CROSS-REFERENCE TO RELATED APPLICATIONS

This is a Continuation of U.S. patent application Ser. No. 16/782,802 filed on Feb. 5, 2020, which claims the benefit of Japanese Patent Application No. 2019-020340 filed on Feb. 7, 2019 including the specification, drawings and abstract are incorporated herein by reference in their entirety.

### BACKGROUND

The present invention relates to a semiconductor device and a manufacturing method thereof, in particular it can be suitably used for a semiconductor device with a power MOSFET(Metal Oxide Semiconductor Field Effect Transistor).

In a semiconductor element such as a power MOSFET, there is an PN junction so called super junction structure for improving withstand voltage in a semiconductor device.

The withstand voltage can be improved, for example, by forming depletion layer around a p-type column region by two-dimensionally arranging the p-type column region in an N-type drifting area, in case of an n-type MOSFET.

There are disclosed techniques listed below.

[Patent Document 1] Japanese Unexamined Patent Application Publication No. 2010-16309

[Patent Document 2] Japanese Unexamined Patent Application Publication No. 2008-16518

[Patent Document 2] Japanese Unexamined Patent Application Publication No. 2014-150148

Patent Document 1 discloses a power MOSFET having a super junction structure and a technique using a plurality of p-type column regions arranged in a dot shape so as to be separated from each other has been opened.

On the other hand, Patent Document 2 and Patent Document 3 discloses techniques for forming contact holes to gate electrodes in the outer peripheral region of the power MOSFET.

Patent Document 2 discloses a structure including a portion of the gate electrodes embedded in a trench is lead out on the semiconductor substrate and a contact hole formed above the lead out portion.

Patent Document 3 discloses a structure that a contact hole is directly formed on a top of a gate electrode buried in a trench. By not leading out the gate electrode onto the semiconductor substrate, a mask for forming a lead out portion of the gate electrode is unnecessary, and thus, the need for a photolithography step is eliminated. Therefore, the technique of Patent Document 3 can be miniaturized the chip and the manufacturing cost can be suppressed in compared with the technique of Patent Document 2.

### SUMMARY

Instead of placing the column region in a stripe that is parallel to the extending direction of the gate electrodes, in the case of arranging the column region in a dot shape, since the occupation ratio of the column region is small, the ON-resistance is improved.

Then, in the case of arranging the column region in the dot shape, by arranging a plurality of column regions formed on both sides of the gate electrode in staggering manner, the occupancy rate of the depletion layer extending from the column region can be efficiently improved.

However, difficult areas for depletion occurs depending on the formation position of the plurality of column regions arranged in a staggered manner.

On measures such as increasing the width of the column area could be applied, but this would result in too much column area occupancy and a rising of ON-resistance.

Therefore, it is desired to improve the performance of the semiconductor device such that the formation positions of the plurality of column regions are optimized and suppress of increasing of the on resistance.

Other objects and novel features will become apparent from the description of this specification and the accompanying drawings.

To briefly explain the outline of typical embodiments among the embodiments disclosed in this application is as follows.

A semiconductor device, in one embodiment, includes a semiconductor substrate, a first impurity region of a first conductivity type, a plurality of trenches formed along the inside from the surface of the first impurity region and extending in the first direction in plan view, and a gate electrode formed inside each of the plurality of trenches via a gate insulating film. Also, the semiconductor device includes a plurality of column regions of a second conductivity type opposite to the first conductivity type. Each of the column regions is formed in the first impurity region between the trenches and has a depth that is deeper than the depth of a bottom of the trenches.

The trenches include a first trench, a second trench and a third trench. The second trench and the third trench are adjacent to the first trench so as to sandwich the first trench in a second direction orthogonal to the first direction.

The column regions include a first column region formed between the first trench and the second trench, and a second column region and a third column region formed between the first trench and the third trench.

The second column region and the third column region are adjacent to each other in the first direction. Of the plurality of column regions formed between the first trench and the second trench, the first column region is provided closest to the second column region and the third column region. Further, an angle θ formed by a line connecting the centers of the first column region and the second column region and a line connecting the centers of the first column region and the third column region is 60 degrees or more and 90 degrees or less.

According to one embodiment, the performance of the semiconductor device can be improved.

### BRIEF DESCRIPTION OF THE DRAWINGS

FIG. 1 is a plan view showing a semiconductor chip which is a semiconductor device of a first embodiment.

FIG. 2 is a main portion plan view showing the semiconductor device of the first embodiment.

FIG. 3 is a cross-sectional view showing the semiconductor device of the first embodiment.

FIG. 4 is a main portion plan view showing a semiconductor device of a comparative example.

FIG. 5 is a graph showing the results of experimentation by the inventor of the present application.

FIG. 6 is a main portion plan view showing the semiconductor device of the modified example.

FIG. 7 is a cross-sectional view showing a manufacturing process of the semiconductor device of the first embodiment.

FIG. 8 is a cross-sectional view showing the manufacturing process subsequent to FIG. 7.

FIG. 9 is a cross-sectional view showing the manufacturing process subsequent to FIG. 8.

FIG. 10 is a cross-sectional view showing the manufacturing process subsequent to FIG. 9.

FIG. 11 is a cross-sectional view showing the manufacturing process subsequent to FIG. 10.

FIG. 12 is a cross-sectional view showing the manufacturing process subsequent to FIG. 11. FIG. 13 is a cross-sectional view showing the manufacturing process subsequent to FIG. 12.

FIG. 14 is a cross-sectional view showing the manufacturing process subsequent to FIG. 13.

FIG. 15 is a cross-sectional view showing the manufacturing process subsequent to FIG. 14.

### DETAILED DESCRIPTION

In the following embodiments, a plurality of sections or a plurality of embodiments may be used, if there is necessary for the sake of convenience.

Except where specifically indicated, they are not irrelevant to each other, and one is related to some or all of the other modifications, details, supplementary explanations, and the like.

Further, in the following embodiments, when referring to the number of elements (including the number, numerical value, quantity, range, etc.), especially when clearly indicated and when clearly limited to a specific number in principle, etc. Except, it is not limited to the specific number, and may be more or less than the specific number.

Further, in the following embodiments, the constituent elements (including element steps and the like) are not necessarily indispensable unless otherwise specified and clearly considered essential in principle, needless to say.

Similarly, in the following embodiments, when referring to the shape, positional relationship, etc. of components, etc., the shape is substantially the same unless otherwise specified, or otherwise apparent in principle. And the like are included. The same applies to the above numerical values and ranges.

Hereinafter, embodiments will be described in detail based on the drawings. To explain the embodiment in all the drawings, members having the same function are denoted by the same reference numerals, and the description thereof is repeated. In the following embodiments the same or similar parts except where particularly necessary, in principle, description will not be repeated.

In addition, in the drawings used in the embodiments, the drawings are cross-sectional view for the sake of clarity.

Also, hatching may be omitted, or hatching may be added even if the hatching is plan view.

### First Embodiment

Hereinafter, the semiconductor device of the present embodiment will be described in detail by referring to the drawings. Real truth

MOSFET for controlling high voltages and high currents, and withstands the power.

A plurality of p-type column regions PC are formed inside the n-type drift region ND in order to improve the pressure. A super junction structure is provided.

### Structure of Semiconductor Device

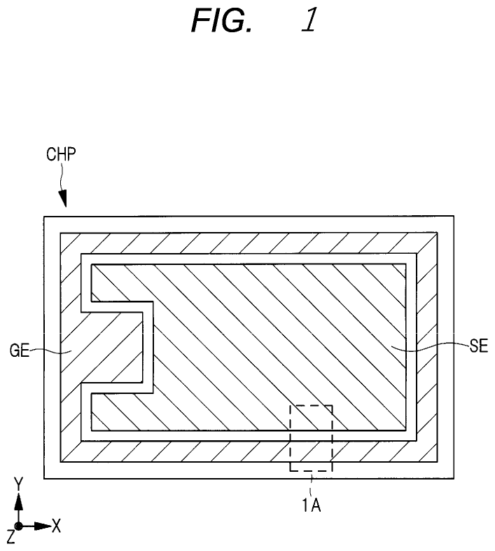

FIG. 1 shows a plan view of a semiconductor chip CHP, which is a semiconductor device of a semiconductor chip CHP in the present embodiment. FIG. 1 is Plan view, but for ease of illustration, gated wiring GEs and source electrodes (source wiring) SE is hatched.

As shown in FIG. 1, most of the semiconductor chip CHP is covered with the source electrode SE, and main semiconductor elements such as a power MOSFET are formed below the source electrodes SE. Gates wiring GEs are formed on the outer peripheries of the source electrodes SEs. By connecting external connections such as wire bonds or copper clips (copper plates) to the source electrodes SE and the gate wiring GEs, it possible to make an electrical connection with the other external chips or wiring substrate.

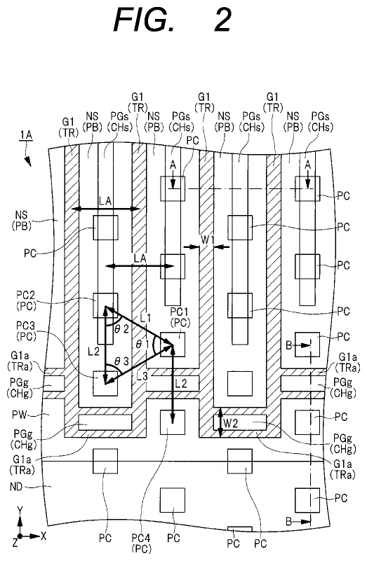

FIG. 2 shows a main portion plan view of the chip CHP, and the region 1A shown by the broken line in FIG. 1 is detailed.

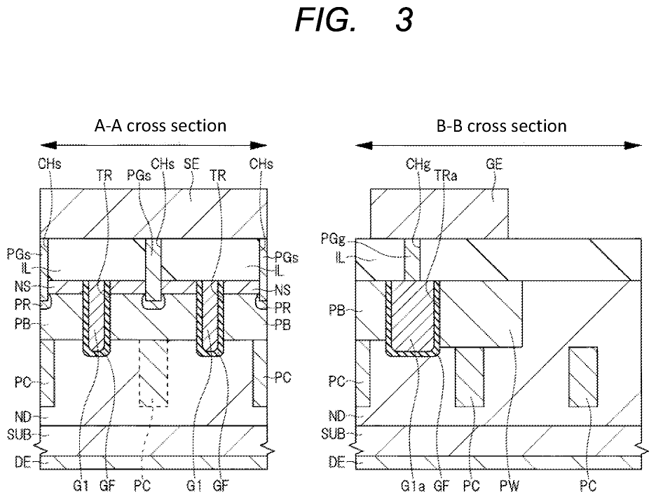

Although FIG. 2 is a plan view, the gate electrode G1 is hatched. FIG. 3 shows the cross-sectional view along lines A-A and B-B shown in FIG. 2. In the A-A cross section of FIG. 3, the relative position of each column region PC is shown.

A column region PC existing in the Y direction is indicated by a broken line.

As shown in FIG. 2, on a part of the surface of the n-type drift region (impurity region) ND, n type source region (impurity region) NS and p type well region (impurity region) PW are provided.

In the drift region ND including the source region NS and the well region PW, a plurality of trenches TR are formed in the Y direction. A gate electrode G1 is formed respectively inside the plurality of trenches TR.

The ends of the plurality of trenches TR are connected by a trench connection portion TRa extending in the X direction orthogonal to the Y direction. Inside the trench connection part TRa, a gate lead-out portion integrated with the gate electrode G1 is formed. A contact hole CHg is arranged above the gate lead portion G1a, and the gate electrode G1 is electrically connected to the gate wiring GE shown in FIG. 1 by a plug PGg formed inside the contact hole CHg.

Width W2 of gate lead-out portion G1a in the Y direction (width W2 of trench connection portion TRa) is larger than the width W1 of the gate electrode G1 (the width W1 of the trench TR) in the X direction. This is because it is preferable to set the width W2 wide in the gate lead portion G1a in consideration of misalignment of the contact hole CHg disposed above the gate lead portion G1a.

In the present embodiment, the width W1 is about 0.5 μm, and the width W2 is about 0.65 μm.

In the present embodiment, the region on the inner side (upper side in the drawing) than the gate lead-out portion G1a is an element formation region in which a semiconductor element such as a power MOSFET is formed. A region located on the outer side (lower side in the drawing) of the gate lead-out portion G1a) is an outer peripheral region (termination region) of the semiconductor chip CHP.

In such an element formation region, a source region NS is formed on the surface of the body region (impurity region) PB.

A contact hole CHs extending in the Y direction is disposed above the source region NS, the source region NS and the body region PB are electrically connected to the source electrode SE shown in FIG. 1 by the plugs PGs formed inside the contact hole CHs.

A plurality of column regions PC are formed in the drift region ND.

In the direction in which the gate electrode G1 extends (Y direction), the plurality of column regions PC are provided at equal intervals so as to be separated from each other by an interval of a distance L2.

The plurality of column regions PC positioned so as to sandwich the gate electrode G1 are arranged in a staggered manner.

In other words, the plurality of column regions PC arranged on the first side surface side of the trench TR and the plurality of column regions PC arranged on the second side surface side of the trench TR opposite to the first side surface side are not adjacent in the X direction, but they are offset in the Y direction and are arranged in a staggered pattern.

In the present embodiment, in order to make the description of the features of the present invention easier to understand, some of the plurality of column regions PC are denoted by reference numerals such as PC1 to PC4. Among the plurality of column regions PC formed on the first side surface side of the trench TR, the column region PC1 is formed on the second side surface side of the trench TR that is opposite to the first side surface side in the X direction. It is provided closest to the column area PC2 and the column area PC3. Further, the column region PC2 and the column region PC3 are adjacent to each other in the Y direction, and the column region PC4 is adjacent to the column region PC1 so as to sandwich the gate lead portion G1a in the Y direction.

In the Y direction, the formation positions of the column area PC1 and the column area PC4 are shifted from the formation positions of the column area PC2 and the column area PC3 by half of the distance L2, respectively. In other words, in the Y direction, the center of each of the column region PC1 and the column region PC4 is located between the centers of the column region PC2 and the column region PC3, and is a distance from the centers of the column region PC2 and the column region PC3. The distance is half of L2. The distance from the column area PC1 to the column area PC2 is the distance L1, and the distance from the column area PC1 to the column area PC3 is the distance L3.

More specifically, the distance L1 is a distance from the center of the column area PC1 to the center of the column area PC2, and the distance L2 is a distance from the center of the column area PC2 to the center of the column area PC3. The distance L3 is a distance from the center of the column area PC1 to the center of the column area PC3. The distance connecting the centers of the column regions PC1 and PC4 adjacent to each other across the gate lead portion G1a is also the distance L2. In the present embodiment, the values of the distances L1 to L3 are the same.

Here, when the pitch between the plurality of gate electrodes G1 in the X direction is the distance LA, in other words, the distance connecting the centers of the two gate electrodes G1 in the X direction is LA, the distance L1. The value of ˜L3 is (2/√3)×LA.

In the present embodiment, the distance LA is about 1.2 μm.

As can be seen from the above relationship, in the present embodiment, equilateral triangles are formed by lines connecting the centers of the column regions PC1 to PC3. That is, an angle θ1 formed by a line connecting the centers of the column region PC1 and the column region PC2 and a line connecting the centers of the column region PC1 and the column region PC3 is 60 degrees. An angle θ2 formed by a line connecting the centers of the column area PC1 and the column area PC2 and a line connecting the centers of the column area PC2 and the column area PC3 is 60 degrees. An angle θ3 formed by a line connecting the centers of the column area PC1 and the column area PC3 and a line connecting the centers of the column area PC2 and the column area PC3 is 60 degrees.

Thus, the main feature of the present embodiment is that an equilateral triangle is formed by lines connecting the centers of the column regions PC1 to PC3. This feature will be described later using comparative examples and the like. This will be described in detail.

In the present embodiment, the column area PC is represented by a rectangle. However, in practice, the column area PC is often a circle or a polygon close to a circle because of the resolution of photolithography. However, even if the column area PC has such a shape, the above relationships (lines connecting the centers of the column area PC1 and the column area PC2) are similarly established.

Next, a cross-sectional configuration of the semiconductor device of the present embodiment will be described with reference to FIG. 3.

The semiconductor substrate SUB is made of silicon into which high-concentration n-type impurities are introduced. On the semiconductor substrate SUB, an n-type drift region ND that is an impurity region having a lower concentration than the semiconductor substrate SUB is formed. The drift region ND is formed by, for example, an epitaxial growth method, and is a semiconductor layer made of, for example, silicon. A drain electrode (drain wiring) DE is formed on the back side of the semiconductor substrate SUB. The drain electrode DE is made of, for example, a metal film containing titanium, nickel, and silver.

In the element formation region shown in the A-A cross section, a p-type body region PB is formed in the drift region ND, and in the outer peripheral region shown in the B-B cross section, a p-type well region PW is formed in the drift region ND.

The well region PW is provided to improve the breakdown voltage in the outer peripheral region, the impurity concentration of the well region PW is lower than the impurity concentration of the body region PB, and the depth of the well region PW is deeper than the depth of the body region PB. It has become. Further, the well region PW may be formed so as to extend over a part of the element formation region. If the breakdown voltage of the outer peripheral region can be sufficiently secured, the formation of the well region PW may be omitted, and the body region PB may be formed instead of the well region PW.

A plurality of trenches TR are formed from the surface of the drift region ND to the inside. The depth of trench TR is deeper than the depth of each of body region PB and well region PW, for example, 2 to 5 μm. Inside the trench TR, a gate electrode G1 is embedded via a gate insulating film GF.

As shown in the BB cross section, a part of the trench TR is a trench connection part TRa for connecting a plurality of trenches TR extending in the Y direction.

A trench lead-out portion G1a integrated with the gate electrode G1 is buried in the trench connection portion TRa via the gate insulating film GF. Further, the gate insulating film GF is, for example, a silicon oxide film, and the gate electrode G1 and the gate lead-out portion G1a are, for example, a polycrystalline silicon film into which an n-type impurity is introduced.

As shown in the AA cross section, a source region NS that is an n-type impurity region is formed on the surface side of the body region PB. The impurity concentration of the source region NS is higher than the impurity concentration of the drift region ND. An interlayer insulating film IL made of, for example, a silicon oxide film is formed on the surfaces of the source region NS, the body region PB, and the gate electrode G1. A contact hole CHs and a contact hole CHg are formed in the interlayer insulating film IL.

The contact hole CHs penetrates the interlayer insulating film IL and the source region NS and reaches the inside of the body region PB. A plug PGs having a barrier metal film and a conductive film is embedded in the contact hole CHs.

The barrier metal film is, for example, a laminated film of a titanium film and a titanium nitride film, and the conductive film is, for example, a tungsten film.

In the body region PB at the bottom of the contact hole CHs, a p-type contact region (impurity region) PR having an impurity concentration higher than that of the body region PB is formed. Contact region PR is provided as a part of body region PB, and is provided in order to reduce the contact resistance between plug PGs and body region PB and to prevent latch-up. For this reason, depending on the product specifications, the contact region PR is not essential, and the body region PB may not be provided with the contact region PR. [0041]A source electrode SE made of, for example, an aluminum film is formed on the interlayer insulating film IL so as to be connected to the plugs PGs. Accordingly, the source region NS, the contact region PR, and the body region PB are electrically connected to the source electrode SE via the plug PGs.

As shown in the BB cross section, the contact hole CHg penetrates the interlayer insulating film IL and reaches the gate lead portion G1a. A plug PGg having the same structure as the plug PGs is embedded in the contact hole CHg. A gate wiring GE made of, for example, an aluminum film is formed on the interlayer insulating film IL so as to be connected to the plug PGg. Therefore, the gate electrode G1 is electrically connected to the gate wiring GE through the plug PGg.

Inside the drift region ND, a plurality of column regions PC (PC1 to PC4) that are p-type impurity regions are formed. The plurality of column regions PC are not formed immediately below the trench TR so as to be positioned between the trenches TR. In other words, the plurality of column regions PC are formed at positions that do not overlap the trench TR in plan view. Further, the bottom of column region PC is formed at a position deeper than the bottom of each of trench TR, body region PB and well region PW, and is formed so as to be in contact with body region PB and well region PW. Therefore, the column region PC of the element formation region is electrically connected to the source electrode SE via the body region PB. For this reason, when the source potential is applied from the source electrode SE to the body region PB, the source potential is also applied to the column region PC.

### Comparative Example

Hereinafter, a comparative semiconductor device will be described with reference to FIG. Since the semiconductor device of the comparative example has almost the same structure as the semiconductor device of this embodiment, the description of the overlapping structure is omitted here, and the differences from the semiconductor device of this embodiment are only described.

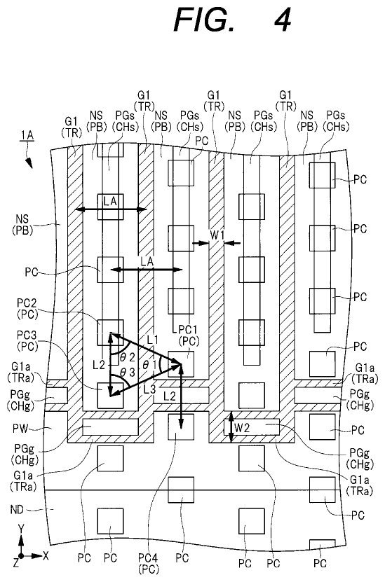

As shown in FIG. 4, in the comparative example, the distance L1 is equal to the distance L3 as in the present embodiment, but the distance L2 is shorter than the distance L1 and the distance L3, unlike the present embodiment. That is, the angle θ1 is less than 60 degrees, and is about 40 degrees here. It is noted that the angle θ2 and the angle θ3 in the comparative example are each about 70 degrees.

For this reason, in the comparative example, there is a problem that depletion is insufficient between the column region PC1 and the column region PC2 or between the column region PC1 and the column region PC3. This is because the distance L1 and the distance L3 are longer than the distance L2 even if the depletion is sufficient between the column area PC2 and the column area PC3.In order to solve this problem, it is conceivable to increase the size of each of the column regions PC1 to PC3. However, if this is done, the occupancy of the column region PC increases so much and then the ON-resistance increases.

Further, in the comparative example, as in Patent Document 3, in order to reduce the size of the chip and reduce the manufacturing cost, the contact hole CHg is formed directly on the gate lead part G1a embedded in the trench connection part TRa. For this reason, also in the comparative example, it is preferable to set the width W2 of the trench connection portion TRa to be larger than the width W1 of the trench TR in consideration of misalignment of the contact hole CHg as in the present embodiment.

However, since the distance L2 of the comparative example is shorter than the distance L2 of the present embodiment, when the width W2 of the trench connection part TRa is wide, the trench connection part TRa and the column region PC may interfere with each other. That is, the column region PC is formed so as to be in contact with the bottom of the trench connection portion TRa, thereby causing a problem that the breakdown voltage of the power MOSFET is deteriorated. Further, if the width W2 of the trench connection part TRa is narrowed, a margin cannot be secured when the contact hole CHg is formed.

As described above, in the semiconductor device of the comparative examples, it is difficult to optimize the widths W2 of the trench connection part TRa.

In addition, it is difficult to achieve both miniaturization of the semiconductor element and suppression of breakdown voltage deterioration.

### Main Features of the Semiconductor Device of This Embodiment

Hereinafter, main features of the semiconductor device of the present embodiment will be described.

As described above, in the present embodiment, the distances L1 to L3 are the same, When the distance connecting the centers of the two gate electrodes G1 in the X direction (the pitch between the plurality of gate electrodes G1) is the distance LA, the values of the distances L1 to L3 are (2 /√3)×LA. The angles Θ1 to θ3 are 60 degrees respectively, and equilateral triangles are formed by lines connecting the centers of the column regions PC1 to PC3.

For this reason, the depletion layer extending from each of the column regions PC1 to PC3 is easily made uniform, and the depletion easily occurs between the column regions PC1 to PC3. Accordingly, it is possible to suppress problems such as increasing the occupancy of the column region PC and increasing the ON-resistance, such as increasing the size of each of the column regions PC1 to PC3.

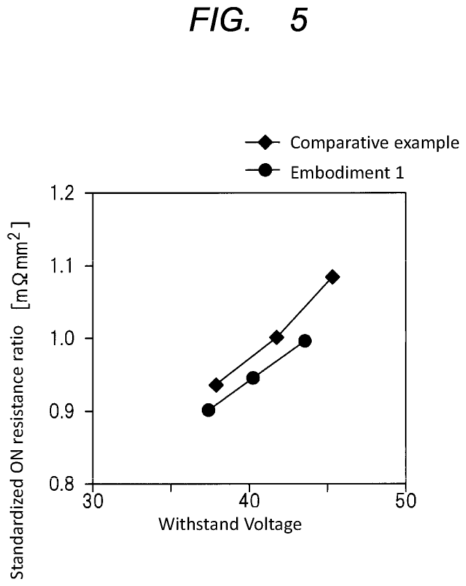

FIG. 5 is a graph showing the results of experiments conducted by the inventors of the present application. In FIG. 5, the vertical axis represents the standardized ON-resistance ratio, and the horizontal axis represents the Withstand voltage value.

The mark of black circle indicates the data of the semiconductor device of this embodiment, the black square indicates data of the semiconductor device of the comparative example. In the experiment of FIG. 5, measurement results are shown in which the size (thickness) of the column region PC is changed in three ways.

As can be seen from the measurement results of FIG. 5, if the size of the column region PC is the same, the semiconductor device of this embodiment can reduce the ON-resistance while ensuring substantially the same breakdown voltage as compared with the semiconductor device of the comparative example. Therefore, according to the present embodiment, the performance of the semiconductor device can be improved.

Further, the distance L2 between the center of the column region PC1 and the center of the column region PC4 of the present embodiment is longer than the distance L2 of the comparative example. Therefore, a wide trench connection portion TRa can be provided between the column region PC1 and the column region PC4 so that the trench connection portion TRa and the column region PC do not interfere and the breakdown voltage of the power MOSFET does not deteriorate. Since the width W2 of the trench connection part TRa can be set wide, the margin of the formation position of the contact hole CHg provided above the gate lead part G1a can be increased. That is, in the semiconductor device of the present embodiment, it is easy to achieve both miniaturization of a semiconductor element and suppression of breakdown voltage degradation as compared with the semiconductor device of the comparative example.

### Semiconductor Device of Modification

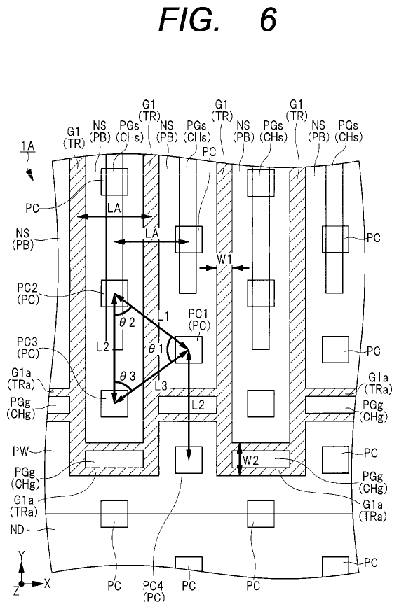

FIG. 6 shows the main portion plan view of the semiconductor device of the first embodiment's modified example.

As shown in FIG. 6, in the modification, the distance L2 between the column region PC2 and the column region PC3 adjacent to each other in the Y direction is longer than that in the first embodiment. Therefore, the distance L1 and the distance L3 are the same, but are shorter than the distance L2. As a result, an isosceles triangle having an angle θ1 larger than 60 degrees is formed by a line connecting the centers of the column regions PC1 to PC3.

In the modification, there is a problem that depletion is insufficient between the column region PC2 and the column region PC3.The reason is that the distance L2 is longer than the distance L1 and the distance L3 even if the depletion is sufficient between the column area PC1 and the column area PC2 or between the column area PC1 and the column area PC3. Because. In order to solve this, it is conceivable to increase the size of each of the column regions PC1 to PC3. However, in that case, in the modified example, as compared with the first embodiment, the occupation ratio of the column region PC is increased, and the ON-resistance is easily increased. In this respect, the semiconductor device of the first embodiment is superior to the semiconductor device of the modification.

However, in the modification, since the distance L2 between the center of the column region PC1 and the center of the column region PC4 is longer, A wide trench connection part TRa that is larger than that of the first embodiment, can be provided between the column region PC1 and the column region PC4. Alternatively, the value of the width W2 of the trench connection part TRa can be maintained even when the miniaturization of the semiconductor element is advanced.

For example, in Embodiment 1, the distance LA is about 1.2 μm, the width W1 is about 0.5 μm, and the width W2 is about 0.65 μm. However, in the modification, the value of the width W2 is possible to set larger than 0.65 μm. Alternatively, the value of the width W2 can be maintained even when the values of the distance LA and the width W1 are reduced due to miniaturization of the semiconductor element.

For this reason, in a modification, it can control that trench connection part TRa and column field PC interfere, and the proof pressure of power MOSFET deteriorates, the margin of the formation position of the contact hole CHg provided above the gate lead portion G1a can be increased. That is, as compared with the semiconductor device of the first embodiment, the modified semiconductor device has an effect that it is easy to further promote the miniaturization of the semiconductor element and an effect that it is easy to further suppress the deterioration of the breakdown voltage.

As described above, if the angle θ1 is large and the distance L2 is too long, it is difficult to sufficiently deplete the region between the column region PC2 and the column region PC3 even if the column region PC is increased in size.

Hereinafter, appropriate numerical values of main components in the semiconductor device according to the modification will be described.

In the modification, the angle θ1 is greater than 60 degrees and equal to or less than 90 degrees, and the angles θ2 and θ3 are greater than or equal to 45 degrees and less than 60 degrees, respectively. When the pitch between the plurality of gate electrodes G1 is the distance LA, the distance L1 is equal to the distance L3, and is larger than (2 /√3)×LA and is equal to or smaller than √2×LA, and distance L2 is different from the distance L1 and the distance L3 respectively, and is larger than (2 /√3)×LA and 2×LA or less.

That is, when the first embodiment and the modification are summarized, the semiconductor device of the present application can be appropriately used by setting the numerical values of the main components within the following ranges.

The angle θ1 is not less than 60 degrees and not more than 90 degrees. The angle θ2 and the angle θ3 are 45 degrees or more and 60 degrees or less, respectively. The total value of the angles θ1 to θ3 is 180 degrees. The distance L1 and the distance L3 are (2 /√3) X LA or more and √2×LA or less, respectively. The distance L2 is (2 /√3)×LA or more and 2×LA or less.

### Method of Manufacturing Semiconductor Device

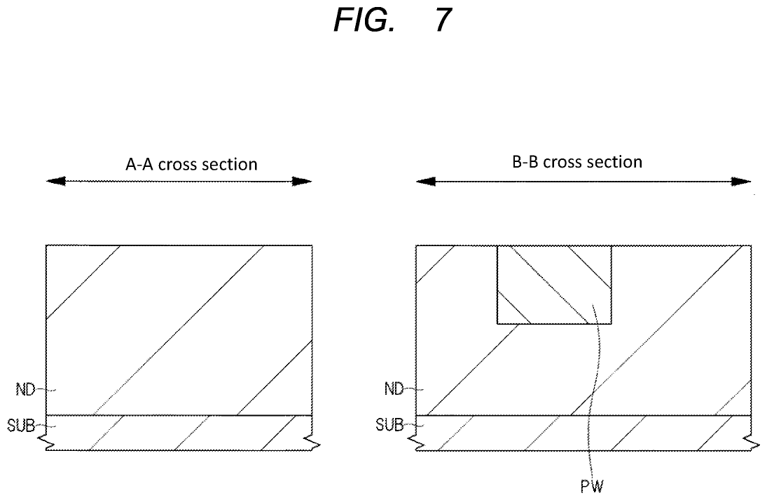

The manufacturing method of the semiconductor device of the first embodiment will be described below with reference to FIGS. 7 to 15.

FIGS. 7 to 15 are manufacturing processes of the A-A cross section and the B-B cross section shown in FIG. 3.

Since the structure of the above-described modification is substantially the same as the manufacturing method of the first embodiment except for the planar layout of the plurality of column regions PC, the manufacturing method of the first embodiment will be described below as a representative example.

FIG. 7 shows a step of forming the drift region ND and the well region PW.

First, an n-type semiconductor substrate SUB made of a semiconductor such as silicon is prepared. Next, a silicon layer (semiconductor layer) is formed on the semiconductor substrate SUB by epitaxial growth, while introducing, for example, phosphorus (P). Thereby, an n-type drift region ND having an impurity concentration lower than that of the semiconductor substrate SUB is formed on the semiconductor substrate SUB. Next, a well region PW is formed on the surface of the drift region ND in the outer peripheral region by using a photolithography technique and an ion implantation method. Thereafter, heat treatment may be performed for activation and diffusion of each impurity.

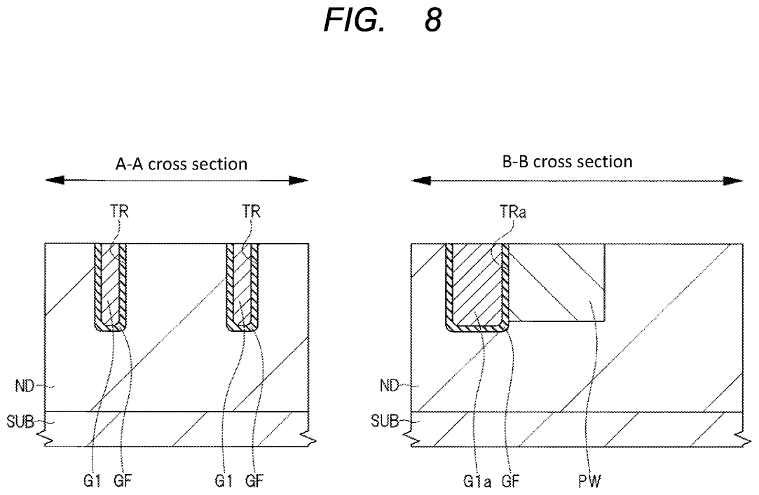

FIG. 8 shows step of forming trenches TR, trench connections TRa, gate dielectric film GF, and gate electrodes G1.

First, the trench TR and the trench connection portion TRa are formed on the surface and inside of the drift region ND so as to be deeper than the depth of the well region PW by etching the drift region ND by a photolithography technique and a dry etching process. Here, as shown in FIG. 2, the trench TR is formed so as to extend in the Y direction in plan view, and the trench connection portion TRa connects the plurality of trenches TR each other and is formed to extend in the X direction.

Next, a gate insulating film GF made of, for example, a silicon oxide film is formed on the inner wall of the trench TR, the inner wall of the trench connection portion TRa, and the drift region ND by thermal oxidation. This thermal oxidation treatment is performed, for example, under conditions of 800 to 950° C. and 1 to 3 minutes.

Next, a conductive film is formed on the gate insulating film GF by, for example, a CVD (Chemical Vapor Deposition) method so as to fill the inside of the trench TR and the inside of the trench connection part TRa. The conductive film is, for example, a polycrystalline silicon film into which an n-type impurity is introduced.

Next, the conductive film is etched and patterned by performing dry etching using the gate insulating film GF formed over the drift region ND as an etching stopper. As a result, the conductive film formed outside the trench TR and outside the trench connection portion TRa is removed selectively, and the gate electrode G1 is formed inside the trench TR via the gate insulating film GF, a gate lead-out portion G1a is formed inside the trench connection portion TRa via a gate insulating film GF. Thereafter, the gate insulating film GF formed over the drift region ND may be remained, but here, the gate insulating film GF over the drift region ND is removed by wet etching or the like.

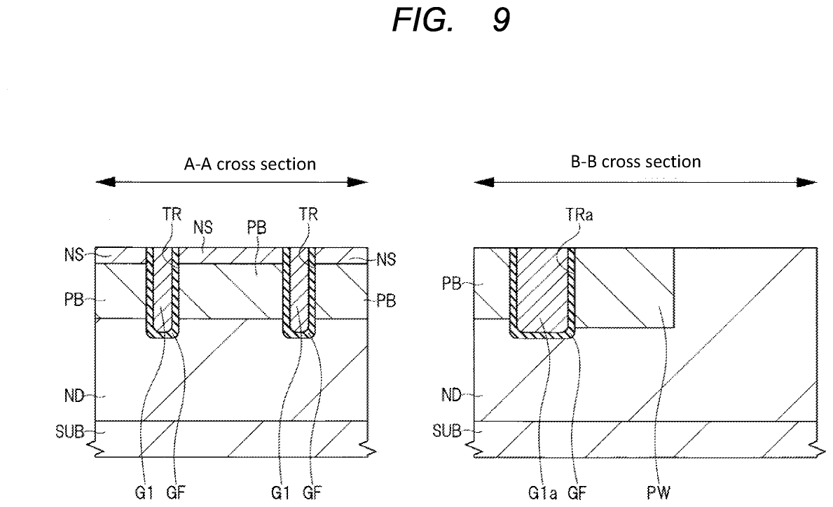

FIG. 9 shows a step of forming the body region PB and the source region NS.

First, by photolithography and ion implantation using boron (B), a p-type body region PB is formed on the surface of the drift region ND in the element formation region. The body region

PB is an impurity region having an impurity concentration higher than that of the well region PW, and is formed at a position shallower than the well region PW.

Next, by photolithography technology and ion implantation using arsenic (As), an n-type source region NS is formed on the surface of the body region PB. The source region NS is an impurity region having a higher impurity concentration than the drift region ND.

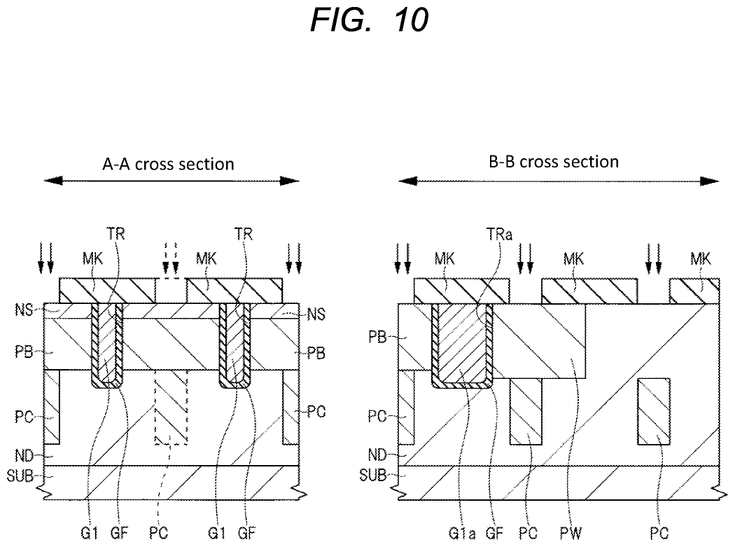

FIG. 10 shows a step of forming the column area PC1˜PC4.

First, an insulating film such as a silicon oxide film or a silicon nitride film is formed on the surface of the drift region ND including the source region NS, the body region PB, and the well region PW by, for example, a CVD method. Next, a plurality of mask layers MK are formed on the surface of the drift region ND by patterning the insulating film by a photolithography technique and a dry etching process.

Next, a plurality of p-type column regions PC are formed in the drift region ND by ion implantation using boron (B) and using the plurality of mask layers MK as a mask. Further, the plurality of column regions PC do not overlap with the trench TR and the trench connection portion TRa in plan view and are formed at a position so as to be in contact with the body region PB or the well region PW. Further, the impurity concentration of the column region PC is approximately the same as the impurity concentration of the body region PB. In addition, this ion implantation process may be performed in multiple steps by changing the energy and dose.

After such an ion implantation process, the mask layer MK is removed by wet etching or the like. Thereafter, heat treatment is performed to activate impurities contained in body region PB, source region NS, and column region PC. This heat treatment for activation is performed in an inert gas atmosphere using nitrogen gas or the like, for example, under conditions of 950 to 1050° C. and about 0.1 second.

The ion implantation process for forming the column region PC can also be performed when the well region PW or the like is formed. However, after that, the column region PC may be diffused beyond the design value and become too thick by a process involving a long-time heat treatment at a high temperature such as a process for forming the gate insulating film GF. Therefore, as shown in FIG. 10, the column region PC formation step is preferably performed after the gate insulating film GF formation step.

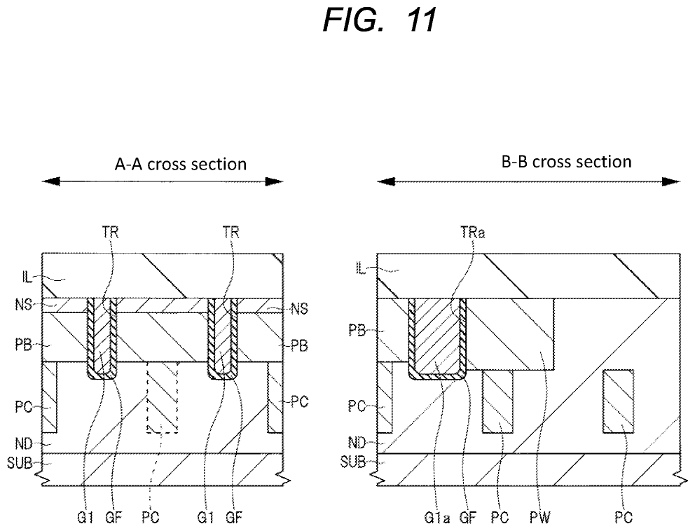

FIG. 11 shows a step of forming the interlayer insulating film IL.

On the surface of drift region ND including source region NS, body region PB and well region PW, for example, the interlayer insulating film IL made of, for example, a silicon oxide film is formed by CVD method.

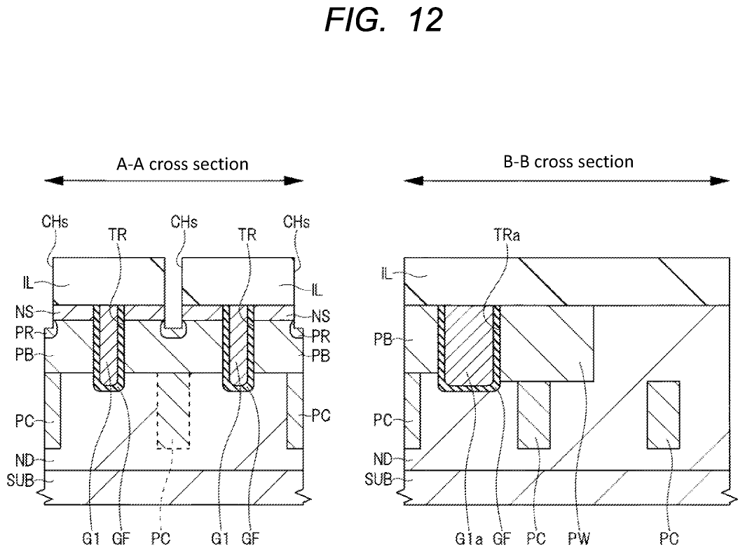

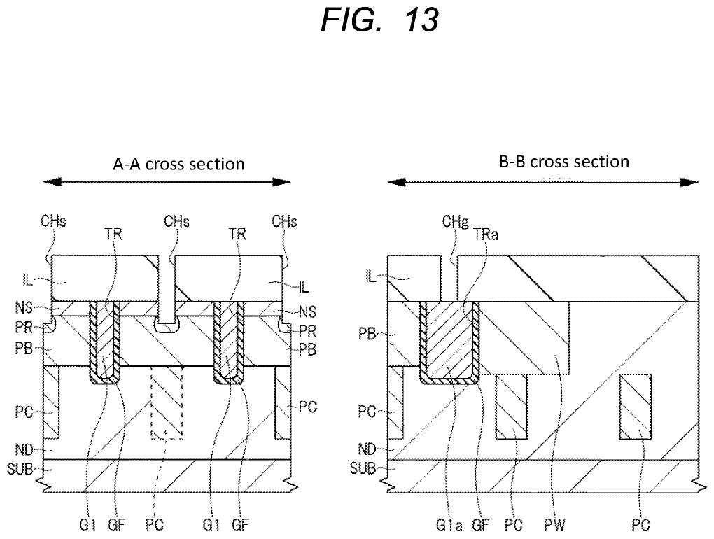

FIG. 12 shows a step of forming the contact hole CHs and the contact region PR.

First, a contact hole CHs that penetrates the interlayer insulating film IL and the source region NS in the element formation region and reaches the body region PB is formed by a photolithography technique and a dry etching process. Next, ion implantation using boron (B) is performed on the bottom of the contact hole CHs, thereby forming a contact region PR having an impurity concentration higher than that of the body region PB inside the body region PB.

FIG. 13 shows a process for forming the contact hole CHg.

A contact hole CHg that penetrates the interlayer insulating film IL in the outer peripheral region and reaches the gate lead portion G1a is formed by photolithography and dry etching.

The contact hole CHs forming step and the contact hole CHg forming step may be performed simultaneously. In that case, since the mask used in the step of forming the contact hole CHg can be reduced, the manufacturing process can be simplified.

However, since the ion implantation process for the p-type contact region PR is performed after the process of forming the contact hole CHs, a p-type impurity is introduced into the gate lead-out portion G1a at the bottom of the contact hole CHg. Accordingly, when the contact hole CHs and the contact hole CHg are formed simultaneously, it is preferable that the n-type impurity concentration contained in the gate lead-out portion G1a is sufficiently high.

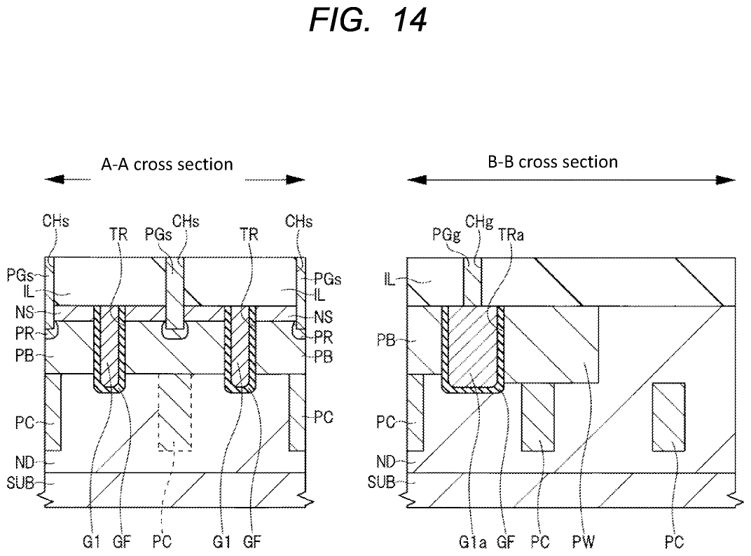

FIG. 14 shows a step of forming the plugs PGs and PGg.

First, so as to embed the inside of the contact hole CHs and the inside of the contact hole CHg, a barrier metal film made of a laminated film of a titanium film and a titanium nitride film is formed on the interlayer insulating film IL by, for example, CVD method or a sputtering method. Next, a conductive film made of a tungsten film is formed on the barrier metal film by, for example, CVD method. Next, the barrier metal film and the conductive film on the interlayer insulating film IL are removed by CMP, so that the barrier metal film and the conductive film are formed in the contact hole CHs and the contact hole CHg, respectively, thereby forming a plug PGs and a plug PGg made of the barrier metal film and the conductive film.

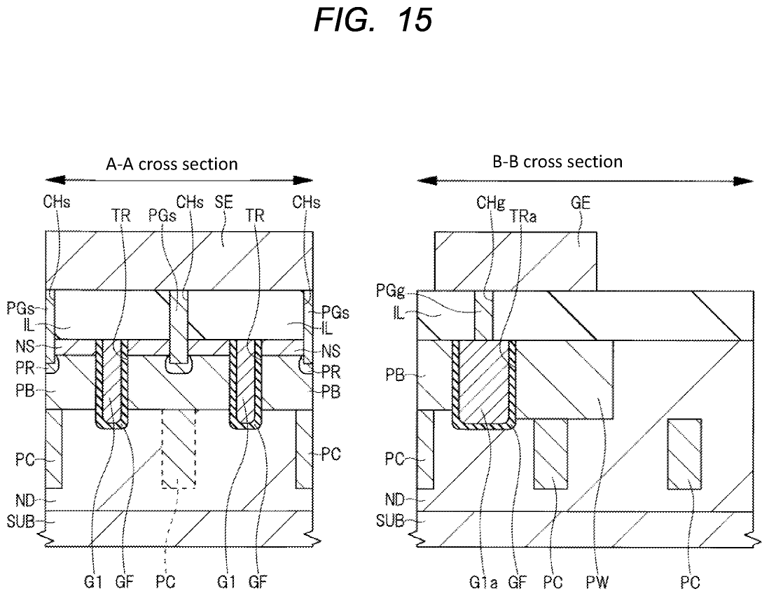

FIG. 15 shows a step of forming the source electrode SE and the gate wiring GE.

First, for example, an aluminum film is formed on the interlayer insulating film IL by, for example, a sputtering method. Next, the aluminum film is patterned using photolithography and dry etching, whereby, the source electrode SE electrically connected to the source region NS and the body region PB via the plug PGs is formed on the interlayer insulating film IL, and a gate wiring GE electrically connected to the gate lead-out portion G1a via the plug PGg is formed.

After the process of FIG. 15, if necessary, the back surface of the semiconductor substrate SUB may be polished to reduce the thickness of the semiconductor substrate SUB. Next, the drain electrode DE made of a metal film containing, for example, titanium, nickel and silver is formed on the back surface of the semiconductor substrate SUB by, for example, sputtering.

As described above, the semiconductor device of the present embodiment shown in FIG. 3 is manufactured.

As mentioned above, although the invention made by this inventor is concretely demonstrated based on embodiment, this invention is not limited to the embodiment, a various change is possible in the range which does not deviate from the summary.

For example, in the above embodiment, an example in which the present invention is applied to an n-type power MOSFET has been described. However, the conductivity of each component may be reversed and the present invention may be applied to a p-type power MOSFET. In addition, a part of the contents described in the above embodiment will be described below.

A Semiconductor device comprising:

a first impurity region of a first conductivity type formed on the semiconductor substrate;

a first trench formed from the surface to the inside of the first impurity region and extending in the first direction in plan view;

a gate electrode formed in the first trench through a gate insulating film; and

a first column region, a second column region and a third column region each formed inside the first impurity region and each having a bottom depth deeper than a depth of the bottom of the first trench, the first to third column regions being of a second conductivity type opposite to the first conductivity type;

wherein the first column region is formed on a first side surface of the first trench, the second column region and the third column region are formed on a second side surface of the first trench opposite to the first side surface side and are adjacent to each other in the first direction,

wherein the center of the first column region is located between the center of the second column region and the center of the third column region in the first direction, and

wherein an angle θ1 formed by a line connecting the centers of the first column region and the second column region and a line connecting the centers of the first column region and the third column region is 60 degrees or more, 90 Less than

In the semiconductor device, an equilateral triangle is formed by a line connecting the centers of the first column region, the second column region, and the third column region.

In the semiconductor device, an isosceles triangle is formed by a line connecting the centers of the first column region, the second column region, and the third column region.

What is claimed is:

1. A semiconductor device comprising:
a semiconductor substrate;
a first impurity region formed on the semiconductor substrate, a conductivity type of the first impurity region being a first conductivity type;
a plurality of trenches formed in the first impurity region and extending in the first direction in plan view;
a gate electrode formed in each of the plurality of trenches, via a gate insulating film; and
a plurality of column regions formed in the first impurity region, each of the plurality of column regions having a bottom portion whose depth is deeper than a depth of a bottom portion of each of the plurality of trenches in cross-sectional view, and a conductivity type of each of the plurality of column regions being a second conductivity type opposite the first conductivity type,
wherein the plurality of trenches includes a first trench, a second trench and a third trench, each of the second trench and the third trench being adjacent to the first trench in plan view such that the first trench is located between the second trench and the third trench in a second direction orthogonal to the first direction in plan view,
wherein the plurality of column regions includes:
a first column region formed in the first impurity region at a portion between the first trench and the second trench in plan view;
a second column region formed in the first impurity region at a portion between the first trench and the third trench in plan view; and
a third column region formed in the first impurity region at a portion between the first trench and the third trench in plan view,
wherein, in plan view, the second column region and the third column region are adjacent to each other in the first direction,
wherein the first column region is one of the plurality of column regions formed between the first trench and the second trench, the one being provided at a portion closest to each of the second column region and the third column region,
wherein, in plan view, a first angle defined by a first line connecting a center of the first column region and a center of the second column region and a third line connecting the center of the first column region and a center of the third column region is greater than 60 degrees, and less than 90 degrees,
wherein a second angle defined by a second line connecting the center of the second column region and the center of the third column region and the first line and is 45 degrees or more, and less than 60 degrees, and
wherein an angle defined by the third line and the second line is 45 degrees or more, and less than 60 degrees.

2. The semiconductor device according to claim 1,
wherein, in the second direction, if a distance between a center of the gate electrode formed inside the first trench and a center of the gate electrode formed inside the second trench or formed inside the third trench is defined as LA, each of a distance from the center of the first column region to the center of the second column region and a distance from the center of the first column region to the center of the third column region is greater than (2/\sqrt{3})×LA, and less than or equal to \sqrt{2}×LA, and
wherein a distance from the center of the second column region to the center of the third column region is greater than (2/\sqrt{3})×LA, and less than or equal to 2×LA.

3. The semiconductor device according to claim 1,
wherein the plurality of trenches further includes a trench connection portion extending in the second direction and connecting each of the first trench and the second trench,
wherein a gate lead-out portion integrated with the gate electrode is formed in the trench connection portion via the gate insulating film,
wherein a width of the trench connection portion is larger than a width of the first trench in the second direction, and
wherein a first plug for connecting to a gate wiring is formed on the gate lead-out portion.

4. The semiconductor device according to claim 2, wherein the plurality of column regions further includes a fourth column region, the fourth column region being formed in the first impurity region such that the gate lead-out portion is located between the first column region and the fourth column region in the first direction, and such that each of the first column region and the fourth column region does not overlap the trench connection portion in plan view.

5. The semiconductor device according to claim 1, further comprising:
a second impurity region formed inside the first impurity region and having a bottom portion whose depth is shallower than the depth of the bottom portion of each of the plurality of trenches, of the second conductivity type in cross-sectional view, a conductivity type of the second impurity region being the second conductivity type;
a third impurity region formed in the second impurity region, a conductivity type of the third impurity region being the first conductivity type;
a contact hole penetrating through the third impurity region so as to reach the second impurity region;
a second plug formed inside the contact hole and electrically connected to each of the second impurity region and the third impurity region; and
a source electrode electrically connected to the second plug,
wherein the plurality of column regions is in contact with the second impurity region.
